(19) United States
(12) Patent Application Publication
(10) Pub. No.: US 2004/0250185 A1
(43) Pub. Date: Dec. 9, 2004

(54) Semiconductor integrated circuit

(75) Inventor: Hisakazu Date, Ome (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/807,446

(22) Filed: Mar. 24, 2004

(30) Foreign Application Priority Data
Mar. 31, 2003 (JP) 2003-094843

(51) Int. Cl. G01R 31/28

(52) U.S. Cl. 714/726

(57) ABSTRACT

A scan diagnosis circuit is constructed to avoid a hold violation by connecting the scan chains so as to flow scan data in the direction opposite to the direction of propagation of a clock signal to accelerate the transition of the clock signal with respect to the scan test data, and by increasing the resistance in the return path beyond that in the clock signal transmission path to delay the data transfer in the return path.

### CLAIM OF PRIORITY

The present application claims priority from Japanese application JP 2003-094843 filed on Mar. 31, 2003, the content of which is hereby incorporated by reference into this application.

### FIELD OF THE INVENTION

The present invention is related to a semiconductor integrated circuit, and, more particularly, to the avoidance of hold violations in scan diagnosis circuits.

### BACKGROUND OF THE INVENTION

For detecting a failure of combination circuit in a semiconductor integrated circuit, the scan test is known in the art (see JP-A No. 2002-76123, paragraph 26, hereafter referred to as Reference #1). To enable the scan test, a scan chain circuit (sometimes referred to as a scan path circuit) is equipped with the combination circuit. The scan chain circuit is formed of a plurality of scan flip-flops each having a scan in node, a scan out node, and clock in node. The scan out node of a scan flip-flop is connected to the scan in node of another adjacent scan flip-flop to form a chain of a number of scan flip-flops. In such a configuration, the data for scan test is sequentially shifted from one scan flip-flop to another, in synchronization with the clock signal.

Basically, the scan chain circuit is configured as a shift register. When the transition of the operating clock is slower than the transition of scan test data, the timing of holding data may become inappropriate. This is called a “hold violation”. It is known that the hold violation can be remedied by adding such delay elements as delay buffers in part to control the amount of delay, based on the result of timing analysis. In order to avoid the increase of surface area occupied by the scan chain circuit, it may be preferable to have less delay elements added. However more delay elements are required when the wirings of the scan chain circuit are not optimized, and, in consequence, the surface area occupied by the scan chain circuit continues to increase. Where a high-density implementation of elements is done, such as the data path in a semiconductor integrated circuit, it will be difficult to secure the space for inserting such delay elements as delay buffers. Although it may be conceivable that a scan flip-flop may incorporate, in advance, a delay element such as the delay buffer, the surface area occupied by the scan flip-flop increases, so that there will not be significant difference in the increase of surface area of the scan chain circuit.

For example, in Reference No. 1, to minimize the increased chip surface area of an LSI due to the implementation of scan path circuit (scan chain circuit), a clock driver is placed at the position where the clock signal is supplied in the direction opposite to the flow direction of scan test data transferred in the scan path circuit. In such a configuration, the transition of clock signal with respect to the scan test data may be increased such that a delay element such as delay buffer will not be needed, so that the increase of chip surface area may be suppressed to minimum.

However, according to the technology disclosed in the above-cited reference, no solution is provided when the scan chain circuits are in a multistage configuration, or when the scan flip-flops are dispersed. The hold violation may occur when the configuration of scan chain circuits is complex such as when the scan chain circuits are multistaged or when the scan flip-flops are dispersed.

### SUMMARY OF THE INVENTION

The present invention has been made in view of the above circumstances and has an object to overcome the above problems and to provide a technology for circumventing a hold violation in the scan diagnosis circuit.

The above and further objects and novel features of the present invention will be apparent from the following detailed description when the same is read in connection with the accompanying drawings.

An exemplary embodiment of the disclosed invention may be summarized as follows:

More specifically, a semiconductor integrated circuit includes a combination circuit and a scan diagnosis circuit capable of performing a scan test of said combination circuit, the scan diagnosis circuit has a first scan chain having a plurality of scan flip-flops connected for operating in synchronization with a clock signal; a second scan chain placed behind the first scan chain, and having a plurality of scan flip-flops connected for operating in synchronization with the clock signal; a first clock buffer for supplying the clock signal in the direction opposite to the flow direction of scan test data that passes through the first scan chain; a second clock buffer for supplying the clock signal in the direction opposite to the flow direction of scan test data that passes through the second scan chain; and a return path for sending the scan test data output from a scan flip-flop placed at the closest position to the first clock buffer in the first scan chain to the scan flip-flop placed at the furthermost position from second clock buffer in said second scan chain.

In the above configuration, the first clock buffer supplies the clock signal in the direction opposite to the flow direction of the scan test data that passes through the first scan chain, and the second buffer supplies the clock signal in the direction opposite to the flow direction of scan test data passing through the second scan chain. In the first scan chain and second scan chain the transition of the clock signal with respect to the scan test data may be increased, thereby the hold violation can be prevented from occurring. By providing a return path for transferring the scan test data output from the scan flip-flop placed at the closest position to the first clock buffer in the first scan chain to the scan flip-flop placed at the furthermost position from the second clock buffer in the second scan chain, the transmission direction of clock signal is aligned among scan chains, such that the second scan chain is placed just behind the first scan chain, and this applies to the case when a plurality of scan chains are multistaged. In addition, since the return path is formed so as to be capable of transmitting the scan test data output from the scan flip-flop placed at the closest position to the first clock buffer in the first scan chain to the scan flip-flop placed at the furthermost position from the second clock buffer in the second scan chain, the flow direction of scan test data is the same as that of clock signal, so that the hold violation may occur therein. However, if the bit width in the first scan chain or second scan chain is larger, the signal path by the return path will be longer, and the wiring resistance thereof also will be larger, resulting in less chance to have a hold violation. In other words, to avoid the hold violation when the transmission direction of scan test data is the same as that of clock signal, it will be sufficient to set the delay between two scan flip-flops mutually connected to a value larger than the sum of clock skew difference between those two scan flip-flops and the holding time of a scan flip-flop. When the transmission length of signal is lengthened by adding the return path while at the same time the wiring resistance increases, a sufficient delay can be obtained, thereby, allowing the hold violation in the return path to be avoided.

To increase the wiring resistance in the return path, the return path is preferably made of finer wiring layer than the transmission line of the clock signal. When the wirings are multilayered and the resistance per unit length is different among layers, the return path is preferably formed by using a material of higher resistance value than the wirings formed for the transmission line of the clock signal.

If the delay by the wiring resistance in the return path is not sufficiently obtained, the occurrence of hold violation may be alternatively avoided by inserting a delay element in an area provided for inserting the delay element on the scan test data transmission path in the return path. The delay-element-insertable area may be predefined in the zone other than the data path so as to facilitate the insertion of a delay element by forming a delay element using the area if the delay element is required to be inserted.

Furthermore, the semiconductor integrated circuit may include a clock buffer for scan test, capable of delaying the output signal of the first clock buffer, and a selector, capable of supplying the output signal of the clock buffer for scan test instead of the output from the first clock buffer at the time of scan test by using the scan chain.

When it includes the clock buffers and a plurality of scan flip-flops dispersed in the area to which the clock signal is supplied from the clock buffer, the transition of the clock signal with respect to the scan test data can be accelerated by serial scan chain connection of scan flip-flops in the order of the largest delay of clock signal from the clock buffer to the scan flip-flops, thereby preventing the hold violation from occurring.

### BRIEF DESCRIPTION OF THE DRAWINGS

The accompanying drawings, which are incorporated in and constitute a part of this specification, illustrate an embodiment of the invention and, together with the description, serve to explain the objects, advantages and principles of the invention. In the drawings,

FIG. 1 is a schematic circuit diagram of a primary part of a semiconductor integrated circuit in accordance with the present invention;

FIG. 2 is a schematic circuit diagram of a scan flip-flop included in the semiconductor integrated circuit;

FIG. 3 is a schematic diagram illustrating an effective path during the normal operation of the scan flip-flop;

FIG. 4 is a schematic diagram illustrating an effective path during the scan shift operation of the scan flip-flop;

FIG. 5 is a schematic circuit diagram of a more specific arrangement of the combination circuit included in the semiconductor integrated circuit;

FIG. 6 is a schematic circuit diagram with a scan logic added to the circuitry shown in FIG. 5;

FIG. 7 is a schematic diagram of a chip layout when adopting the circuit layout shown in FIG. 6;

FIG. 8 is a schematic diagram of a cell layout of the flip-flop;

FIG. 9 is another exemplary embodiment of a scan diagnosis circuit included in the semiconductor integrated circuit;

FIG. 10 is still another exemplary embodiment of a scan diagnosis circuit included in the semiconductor integrated circuit; and

FIG. 11 is yet still another exemplary embodiment of a scan diagnosis circuit included in the semiconductor integrated circuit.

### DETAILED DESCRIPTION OF THE PREFERRED EMBODIMENTS

A detailed description of one preferred embodiment of the present invention will now be given referring to the accompanying drawings.

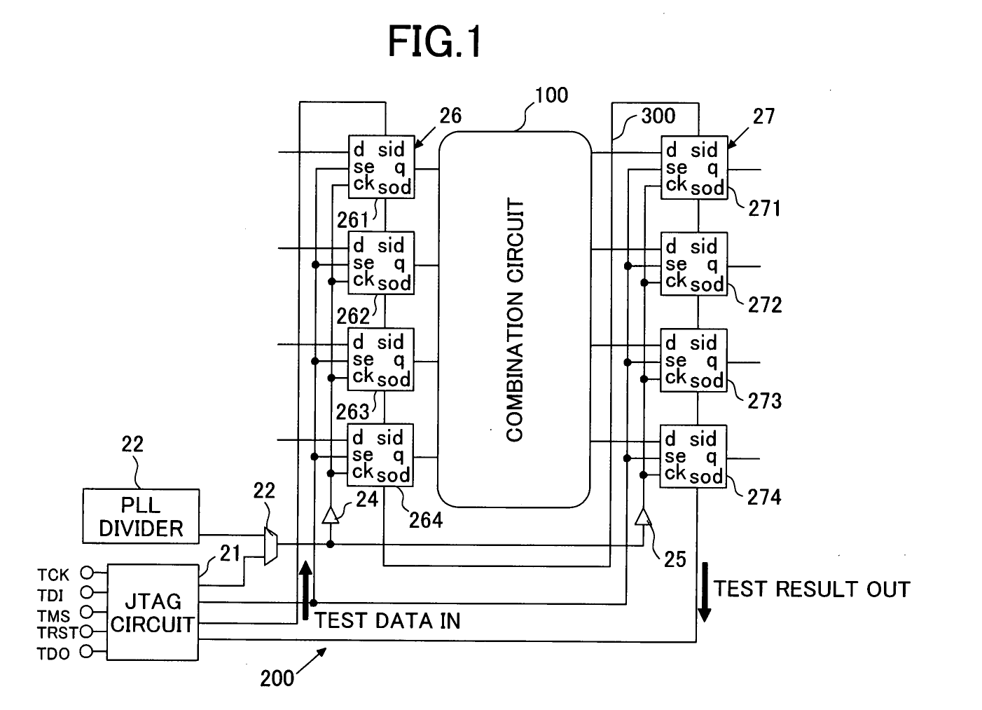

FIG. 1 shows a schematic block diagram of a semiconductor integrated circuit in accordance with the present invention. The semiconductor integrated circuit includes a combination circuit 100, which has a predetermined logic operation function, and a scan diagnosis circuit 200 capable of detecting the failure of the combination circuit 100. The semiconductor integrated circuit may be fabricated on a semiconductor wafer substrate such as a monocrystalline silicon substrate by means of a known semiconductor integrated circuit fabrication technology.

The scan diagnosis circuit 200 includes, but is not limited to, a JTAG circuit 21 (circuit based on the standard according to the Joint Test Action Group), PLL (Phase Locked Loop) divider 22, a clock selector 23, a clock buffer 24 and, 25, and a scan chain 26 and 27.

The JTAG circuit 21 contains five pins defined by the JTAG standard for the purpose of controlling the scan test of the combination circuit 100. These five pins include a TCK (test clock input) pin, a TMS (test mode select input) pin, a TDI (test data input) pin, a TDO (test data output) pin, and a TRST (test reset input active low) pin. The JTAG circuit 21 will generate a variety of signals for scan test control based on the signals applied thereto. These signals include a test clock signal, test data, and a scan mode signal. The test clock signal is transferred to the clock selector 23 placed in the following stage. The clock selector 23 transfers selectively the test clock signal received from the JTAG circuit 21 and the clock signal generated by the PLL divider 22 to the clock buffers 24 and 25 in the following stage.

The scan chain 26 is placed at the side of input terminals of the combination circuit 100 and is connected to, but not limited to, four scan flip-flops 261-264.

The scan chain 27 is placed at the side of output terminals of the combination circuit 100 and is connected to, but not limited to, four scan flip-flops 271-274.

Each of these scan flip-flops 261-264 and 271-274 has a data input terminal d, scan input terminal sid, scan mode terminal se, clock input terminal ck, scan output terminal sod, and data output terminal q.

In the scan chain 26, test data is fed from the JTAG circuit 21 to the scan input terminal sid of the scan flip-flop 261, and the clock signal is fed to the clock input terminal ck through a clock buffer 24. The scan mode terminal se is fed with scan mode signal from the JTAG circuit 21, and the data input terminal d is fed with four bit data from the previous stage not shown in the figure. The data output terminal q is connected to the input terminal of the combination circuit 100. To allow scan in and scan out of the test data, the scan output terminal sod of the scan flip-flop 261 is connected to the scan input terminal sid of the scan flip-flop 262, the scan output terminal sod of which is in turn connected to the scan input terminal sid of the scan flip-flop 263, the scan output terminal sod of which is in turn connected to the scan input terminal sid of the scan flip-flop 264. The scan output terminal sod of the scan flip-flop 264 is then connected to the scan input terminal sid of the scan flip-flop 271 in the scan chain 27. The signal path extending from the scan output terminal sod of the scan flip-flop 264 to the scan input terminal sid of the scan flip-flop 271 is referred to as return path 300.

In the scan chain 27, the scan input terminal sid of the scan flip-flop 271 is fed with the test data output from the scan output terminal sod of the scan flip-flop 264, and the clock input terminal ck is fed with the clock signal through the clock buffer 25. The scan mode terminal se is fed with the scan mode signal from the JTAG circuit 21, and the data input terminal d is fed with four bit data from the combination circuit 100. The data output terminal q is connected to a follower stage not shown in the figure. To enable scan in and scan out of the test data, the scan output terminal sod of the scan flip-flop 271 is connected to the scan input terminal sid of the scan flip-flop 272, the scan output terminal sod of which is in turn connected to the scan input terminal sid of the scan flip-flop 273, the scan output terminal sod of which is then connected to the scan input terminal sid of the scan flip-flop 274. The scan output terminal sod of the scan flip-flop 274 is in turn connected to the JTAG circuit 21 to enable collecting the test result (test data).

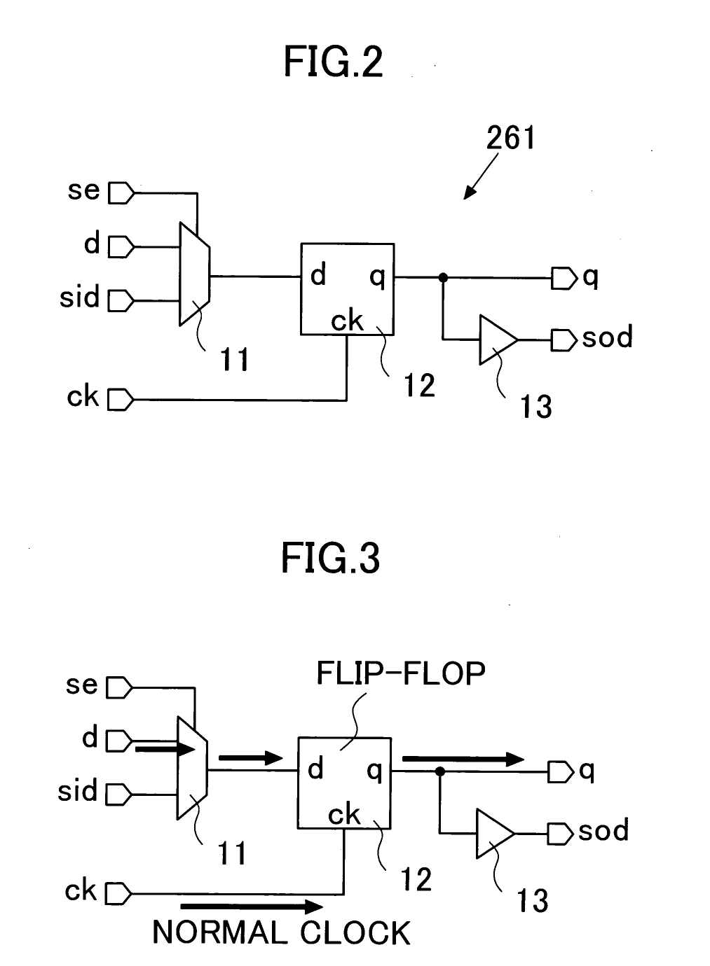

FIG. 2 shows an exemplary embodiment of the scan flip-flop 261.

The scan flip-flop 261 is an edge trigger type, and includes, as shown in FIG. 2, a selector 11, a flip-flop 12, and an output buffer 13. The selector 11 selectively connects either the data input from the data input terminal d or the test data input from the scan input terminal sid to the flip-flop 12 of the following stage, in accordance with the scan mode signal supplied to the scan mode terminal se. Other scan flip-flops 262-264 and 271-274 have the identical configuration as this circuit, and the detailed description of these circuits will be omitted.

The above configuration operates in the normal mode, when the scan mode signal supplied to the scan mode terminal se of the scan flip-flops 261-264 and 271-274 goes low. The scan flip-flops 261-264 and 271-274 hold the data input from the data input terminal d in synchronization with the rising edge of the waveform of normal clock signal (the clock signal generated by the PLL divider 22), and output from the data output terminal q. The output from the circuits in preceding stage (not shown) of the combination circuit 100 will be thereby supplied to the combination circuit 100 through the scan chain 26, while the output data of the combination circuit 100 will be transmit to the circuits of following stage (not shown) through the scan chain 27.

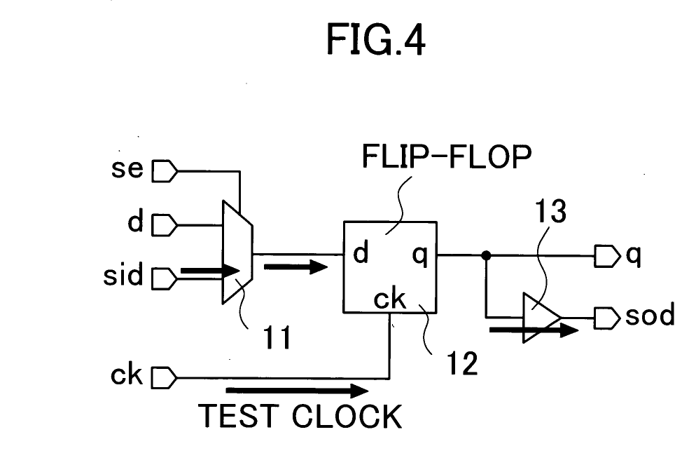

The above configuration operates in the scan shift mode when the scan mode signal goes high, where the test data from the scan input terminal sid is selectively transferred to the data input terminal d of the flip-flop 12 in the scan flip-flops 261-264 and 271-274, as shown in FIG. 4. The data supplied to the data input terminal d will be retained in synchronization with the rising edge of the waveform of clock signal fed to the clock input terminal ck to output on the scan output terminal sod through the output buffer 13.

The scan test on the combination circuit 100 may be performed as follows.

The JTAG circuit 21 supplies test data to the scan chain 26 to set a given value to the scan chain 26 as the input to the combination circuit 100. The data thus setup is input to the combination circuit 100. The output data from the combination circuit 100 at this time is fetched by the scan flip-flops 271-274 in the scan chain 27. The data stored in the scan flip-flops 271-274 will be collected by the JTAG circuit 21 by scan shift operation.

As with the data path structure shown in FIG. 1, if the clock signal propagation sequence is known prior to the automatic wiring of the semiconductor integrated circuit, the connection order of the scan chain may be determined by taking into account the clock skew created by the automatic wiring. More specifically, the scan chains are connected such that the scan data flows in the direction opposite to the direction of clock signal propagation. For example, in the scan chain 26 shown in FIG. 1, the clock signal is transmitted, in sequential order, through the clock buffer 24 to scan flip-flops 264, 263, 262, and then 261. On the other hand the scan data is transmitted to the scan flip-flops 261, 262, 263 and then 264 in that order. In the scan chain 27 shown in FIG. 1, the clock signal will be transmitted to the scan flip-flops 274, 273, 272, and then 271 in that order, while on the other hand the scan data will be transmitted to the scan flip-flops 271, 272, 273, and then 274 in that order. As can be seen from the foregoing, the scan chain is connected so as to flow the scan data in the direction opposite to the flow direction of the clock signal, resulting in accelerating the transmission of the clock signal with respect to the scan test data, to prevent a hold violation from occurring.

With respect to the scan data, the clock signal output from the clock selector 23 will be divided by the clock buffers 24 and 25 to transfer the clock signal in the same direction for the scan chain 26 and scan chain 27, in order to avoid an extreme misalignment of the phases among four bit data output from the data output terminal q of the scan flip-flops 271-274. In order to allow such clock signal propagation, the scan chains 26 and 27 may be connected at the return path 300. However this method may introduce a hold violation because there is a path on which data is transmitted in the same direction as the transmission direction of clock signal output from the clock buffer 25 in the return path 300. This means that the return path 300 is configured capable of sending the scan test data output from the scan flip-flop 264 placed in the closest position to the clock buffer 24 in the scan chain 26 to the scan flip-flop 271 placed in the furthermost position from the clock buffer 25 in the scan chain 27, the transmission direction of scan test data will be equal to that of clock signal, causing a hold violation.

However, the wider the bit-width of the scan chains 26 and 27, the longer the signal transmission path in the return path, and the higher the wiring resistance therein, the less likely a hold violation is to occur. In order to avoid the hold violation when the transmission direction of the scan data is the same as that of clock signal, the delay between two scan flip-flops connected each to other should be increased to a level larger than the sum of the clock skew difference of those two scan flip-flops and the hold time of scan flip-flops. In this way the signal transmission path in the return path 300 can be elongated to increase the wiring resistance, in consequence a sufficient delay can be obtained, thereby preventing the hold violation from occurring in the return path. In the present invention, the wiring resistance of the return path 300 is intentionally increased. For example, if the material used for the wiring layers is same, the wiring layer of the return path 300 is made finer than the wiring layer for the clock signal transmission path, since a finer wiring has a higher resistance. In this manner, the wiring resistance in the return path 300 can be increased to obtain a sufficient delay, and the hold violation therein may be avoided even with the return path 300 and multilayered scan chains 26 and 27.

In accordance with the above-described embodiment, the following effects may be achieved.

(1) In the scan chain 26 the clock signal will flow through the clock buffer 24 to the scan flip-flops 264, 263, 262, 261 in this order, while the scan data will be transmitted to the scan flip-flops 261, 262, 263, and then 264. In the scan chain 27 the clock signal will be propagated via the clock buffer 25 to the scan flip-flops 274, 273, 272, and then 271 in this order, while the scan data will be transmitted to the scan flip-flops 271, 272, 273, and then 274. By connecting the scan chains such that the scan data flows in the direction opposite to the direction of flow of the clock signal, the transition of the clock signal with respect to the scan test data can be accelerated, thereby preventing a hold violation.

(2) In the return path 300, the propagation direction of the clock signal is in parallel to that of the scan test data. Even though this may introduce a hold violation, since the signal propagation path in the return path can be made longer if the bit-width of the scan chains 26 and 27 are wider and as a result the wiring resistance thereof can be augmented, so that a sufficient delay can be obtained while at the same time the hold violation in the return path can be avoided.

(3) If the material used for the wiring layers is the same, a finer wiring has a higher resistance. The wiring layer of the return path 300 can be made finer than the wiring of clock signal transmission path to increase the wiring resistance of the return path 300 so that a sufficient delay can be obtained while at the same time the hold violation in the return path can be avoided.

Now another preferred embodiment of the present invention will be described in greater detail below.

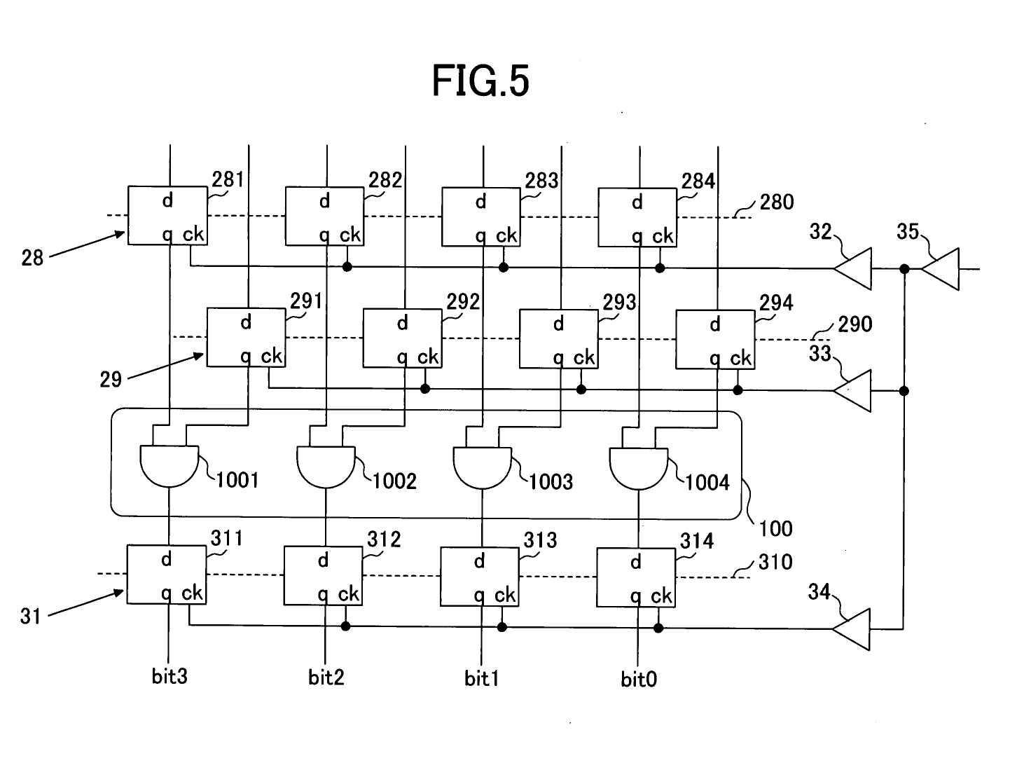

FIG. 5 shows another exemplary embodiment of a combination circuit and a scan chain.

As shown in FIG. 5, if the number of inputs of the combination circuit 100 is different from the number of outputs, for example when the combination circuit 100 is formed from two-input AND gates 1001, 1002, 1003 and 1004, the scan chains in the scan diagnosis circuit may be restructured accordingly. For example, in the structure shown in FIG. 5, there are provided a scan chain 28 corresponding to one input of the two-input AND gates 1001, 1002, 1003 and 1004, another scan chain 29 corresponding to the other input of the two-input AND gates 1001, 1002, 1003 and 1004, as well as a scan chain 31 corresponding to the output terminal of those two-input AND gates 1001, 1002, 1003 and 1004. The scan chain 28 includes four scan flip-flops 281-284, the scan chain 29 includes four scan flip-flops 291-294, and the scan chain 31 includes scan flip-flops 311-314. The scan flip-flops 281-284, 291-294, 311-314 have the identical configuration to that shown in FIG. 2, and form an effective path in accordance with the operation mode as shown in FIGS. 3 and 4. In addition, there are provided a clock buffer for receiving the clock signal fed from the clock selector 23 of FIG. 1 and clock buffers 32, 33, 34 for distributing the output to the scan chains 28, 29, 31, respectively. In FIG. 5 the scan logic for the scan chains 28, 29, 31 are omitted. Each of scan chains 28, 29, 31 are aligned to a virtual line 280, 290, 310 respectively, but not limited thereto. In such arrangement the surface area can be conserved.

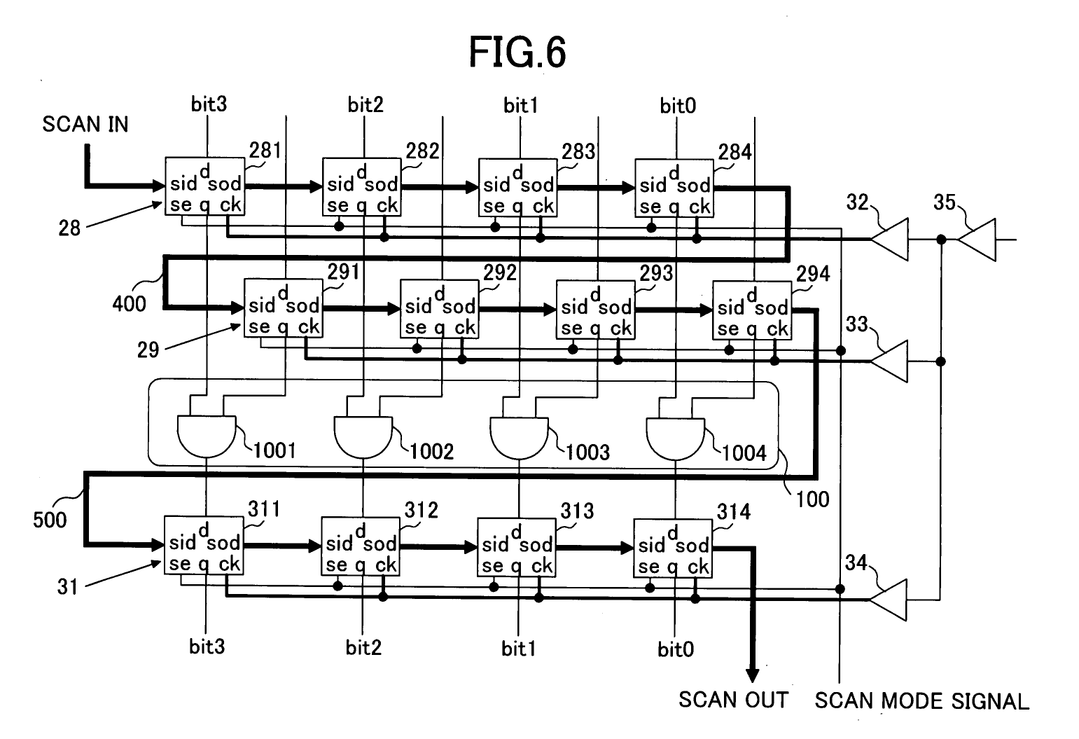

FIG. 6 shows an exemplary embodiment with the scan logic added in the scan chains 28, 29, 31 for the arrangement of FIG. 5.

The scan logic shown in FIG. 6 is basically identical to those shown in FIG. 1. For example, in the scan chain 28, the scan input terminal sid of the scan flip-flop 281 is fed with the test data from the JTAG circuit 21 of FIG. 1, the clock input terminal ck is fed with the clock signal through a clock buffer 32. The scan mode terminal se is fed with the scan mode signal from the JTAG circuit 21 of FIG. 1, the data input terminal d is fed with four bit data from its preceding stage not shown in the figure. The output data from the data output terminal q is sent to one input of the AND gate 1001 in the combination circuit 100. To enable scan in and scan out of the test data, the scan output terminal sod of the scan flip-flop 281 is connected to the scan input terminal sid of the scan flip-flop 282, the scan output terminal sod of which is connected to the scan input terminal sid of the scan flip-flop 283, the scan output terminal sod of which is connected to the scan input terminal sid of the scan flip-flop 284. The scan output terminal sod of the scan flip-flop 284 is in turn connected to the scan input terminal of the scan flip-flop 291. The signal path from the scan output terminal sod of the scan flip-flop 284 to the scan input terminal of the scan flip-flop 291 is referred to as return path 400.

In the scan chain 29, the scan input terminal sid of the scan flip-flop 291 is fed with the test data from the scan flip-flop 284 in the scan chain 28, the clock input terminal ck is fed with the clock signal through a clock buffer 33. The scan mode terminal se is fed with the scan mode signal from the JTAG circuit 21 shown in FIG. 1, the data input terminal d is fed with four bit data from the preceding stage not shown in the figure. The output data from the data output terminal q is transferred to the other input terminal of the AND gate 1001 in the combination circuit 100. To enable scan in and scan out of the test data, the scan output terminal sod of the scan flip-flop 291 is connected to the scan input terminal sid of the scan flip-flop 292, the scan output terminal sod of which is then connected to the scan input terminal sid of the scan flip-flop 293, the scan output terminal sod of which is in turn connected to the scan input terminal sid of the scan flip-flop 294. The scan output terminal sod of the scan flip-flop 294 is further connected to the scan input terminal sid of the scan flip-flop 311. The signal path from the scan output terminal sod of the scan flip-flop 294 to the scan input terminal sid of the scan flip-flop 311 is referred to as return path 500.

In the scan chain 31, the scan input terminal sid of the scan flip-flop 311 is fed with the test data from the scan flip-flop 294 in the scan chain 29, the clock input terminal ck is fed with the clock signal through a clock buffer 34. The scan mode terminal se is fed with the scan mode signal from the JTAG circuit 21 shown in FIG. 1, the data input terminal d is fed with four bit data from the combination circuit 100. The output data from the data output terminal q is transferred to a follower stage not shown in the figure. To enable scan in and scan out of the test data, the scan output terminal sod of the scan flip-flop 311 is connected to the scan input terminal sid of the scan flip-flop 312, the scan output terminal sod of which is then connected to the scan input terminal sid of the scan flip-flop 313, the scan output terminal sod of which is in turn connected to the scan input terminal sid of the scan flip-flop 314. The scan output terminal sod of the scan flip-flop 314 is transferred to the JTAG circuit 21 as the scan chain output. Each of clock buffers 32, 33, 34 is located in the vicinity of flip-flops that ultimately output data in the respective scan chain to feed the clock signal.

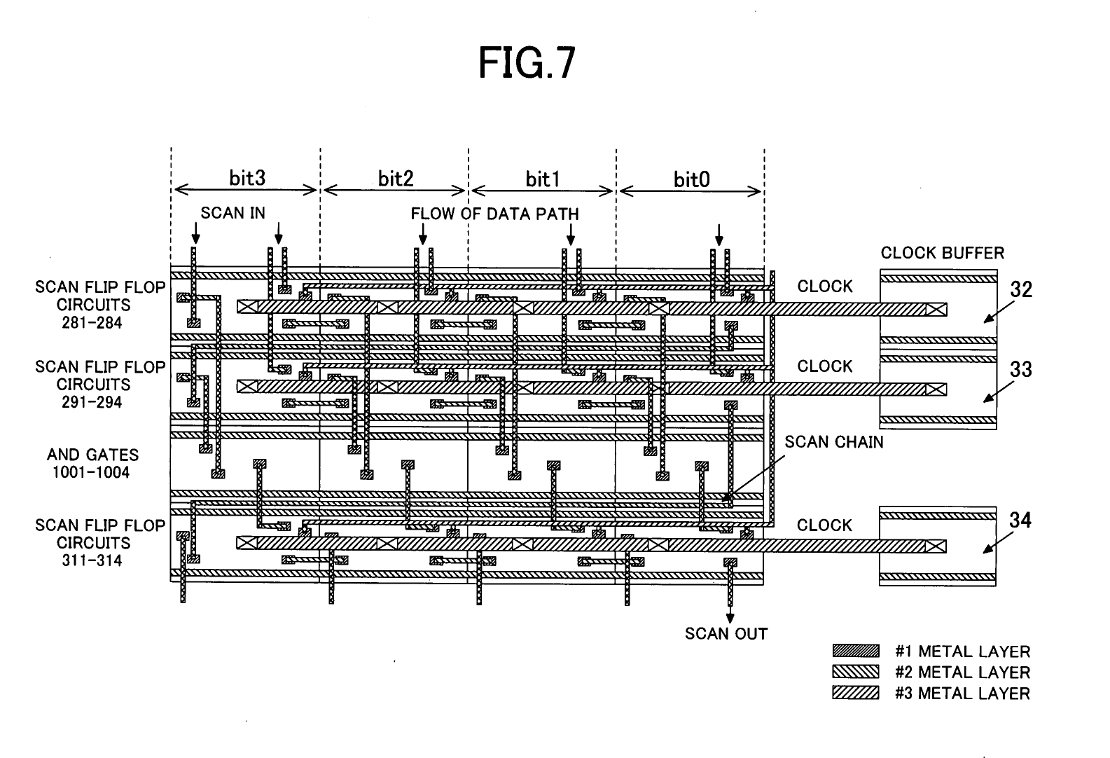

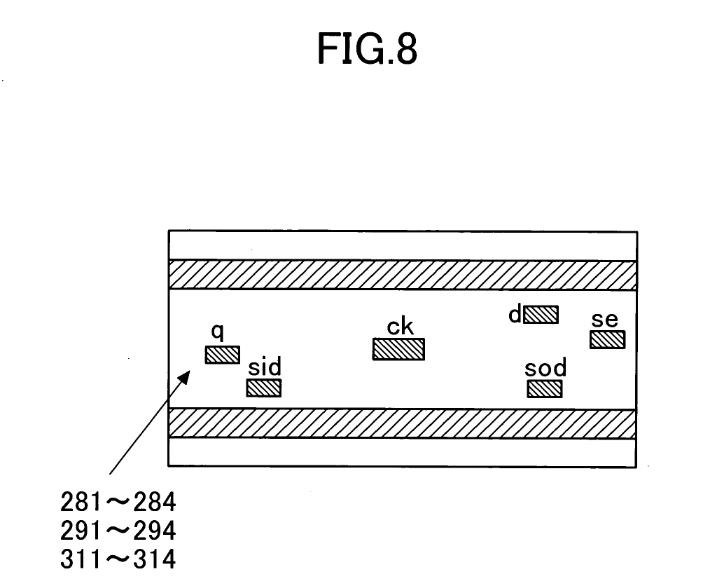

FIG. 7 shows an illustrative layout of the circuit shown in FIG. 6. FIG. 8 is an enlarged view of the terminal layout of one scan flip-flop.

The wirings may be multilayered to three layers of metal, but not limited thereto. If the resistance per unit length is different in layers, a layer having the largest resistance is used for forming the return paths 400 and 500, and other layers having a smaller resistance are used to form signal path of clock signal output from the clock buffers 32, 33, 34. In the layout sample shown in FIG. 7, if metal layer #1 has the largest resistance when compared to the other layers, then metal layer #1 is used for forming the return paths 400 and 500, and metal layer #3, which has a relatively smaller resistance, is used for forming the signal path of clock signal output from the clock buffers 32, 33, 34. The power supply wirings are placed on an upper layer not shown in the figure, and the ultimate supply to the cell is made by using metal layer #1. As can be seen from the foregoing, by increasing the wiring resistance of the return path 400 and the return path 500, a sufficient delay can be obtained for those paths 400 and 500, preventing a hold violation from occurring.

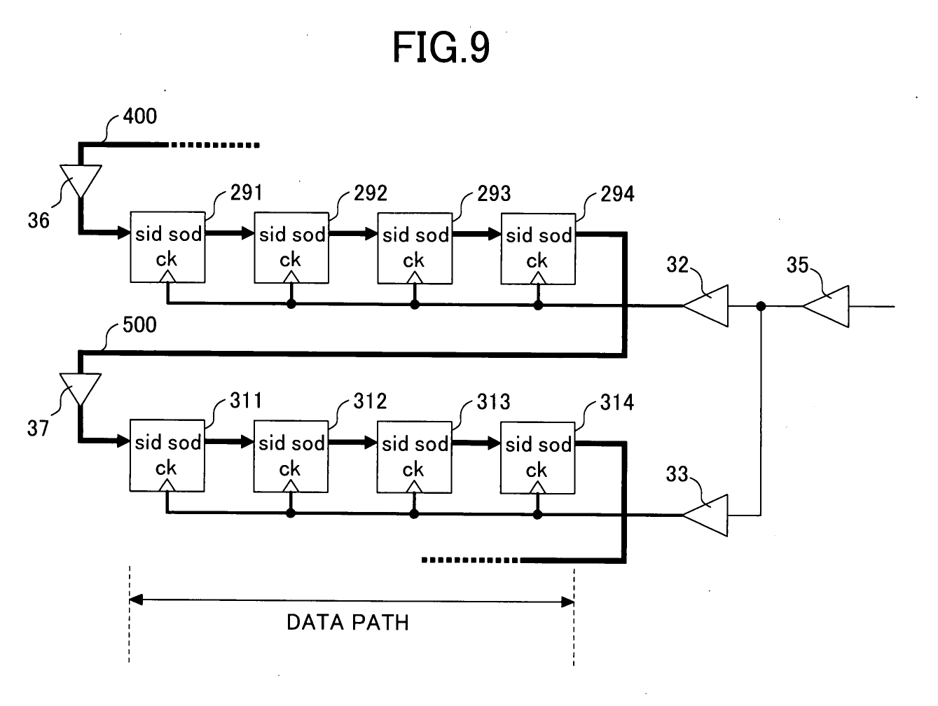

If the hold violation cannot be sufficiently avoided only by increasing the resistance in the return paths 400 and 500 as have been described above such that the resistance in the return paths 400 and 500 is larger than the resistance in the clock signal path to delay the data transmission, some delay buffers 36 and 37 capable of delaying the signal may be inserted into the return paths 400 and 500, as shown in FIG. 9. By providing delay elements such as delay buffers 36 and 37, and by adding a sufficient amount of delay to the return paths 400 and 500, the hold violation can be avoided. In a semiconductor integrated circuit, where a high density implementation of elements such as data paths is routinely done, it is anticipated to be difficult to reserve space for inserting such delay elements as delay buffers, however the area to insert delay elements such as delay buffers 36 and 37 may be predefined in an area other than the data path, in order to form delay elements such as the delay buffers 36 and 37 using the reserved area if the delay elements such as delay buffers are required to be inserted, facilitating the insertion of delay elements such as delay buffers 36 and 37 when needed.

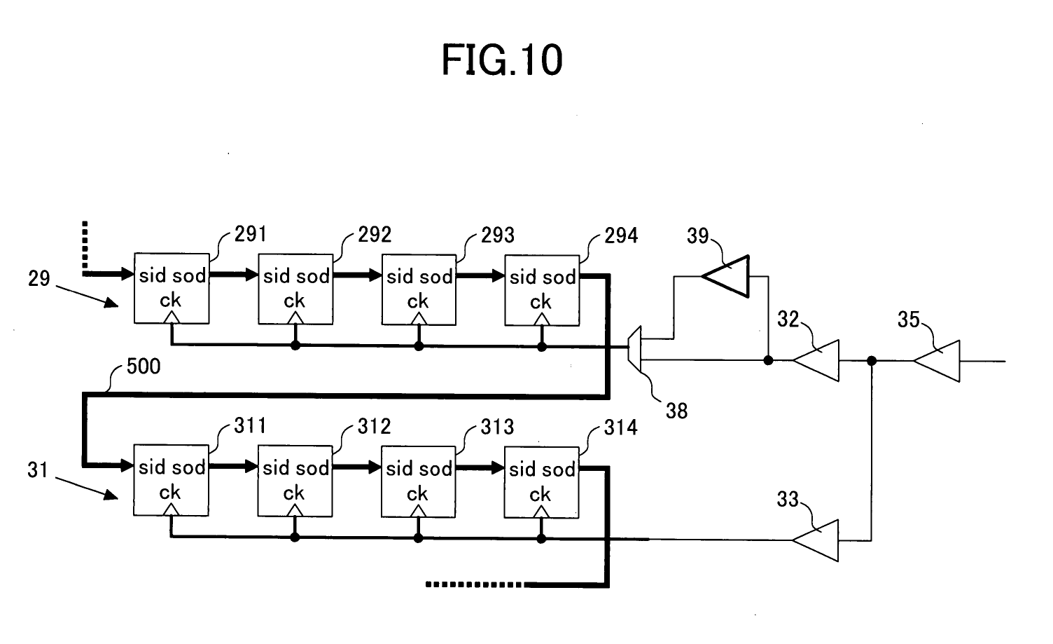

In addition, as shown in FIG. 10, a clock buffer 39 for transmitting the output signal of the clock buffer 32 and a selector 38 for selectively transmitting the output signal of either the clock buffer 32 or the clock buffer 39 to the scan flip-flops 291-294 can be provided. When performing a scan diagnosis, the selector 38 selects the output from the clock buffer 39. The clock signal supplied to the scan chain 29 will thereby be delayed behind the clock signal supplied to the scan chain 31, so that the relationship between the scan flip-flop 294 and the scan flip-flop 311 will be equivalent to a scan flip-flop having an earlier incoming clock signal with respect to the scan flip-flop having an later incoming clock signal, thereby preventing the hold violation caused by the return path 500 from occurring.

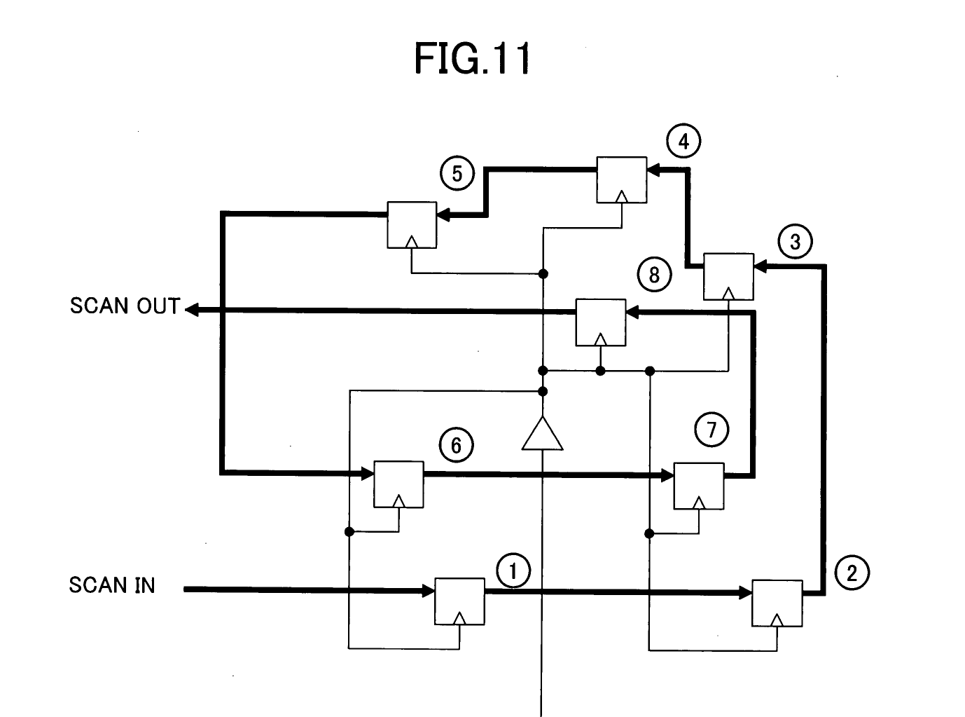

In the above embodiment the scan flip-flops are assumed to be aligned regularly. The present invention may prevent the hold violation when the scan flip-flops are distributed over an area. For example, as shown in FIG. 11, after specifying a service area to supply clock from a predetermined clock buffer 40, and computing the delays of the clock signal up to the scan flip-flops (1) to (8) distributed in the area, a scan chain is connected to those flip-flops in the order of the largest delay. In the figure, scan in designates the test data input, scan out designates the test data output. The scan flip-flops are connected in the scan chain in the order of (1) to (8). In such connection, although the scan flip-flops (1) to (8) are dispersed, a clock driver can be located so as to supply the clock signal in the direction opposite to the flow direction of the scan test data. This enables the transition of clock signal to be accelerated with respect to the scan test data, allowing the hold violation from occurring. In case where the connection order is not respected during the layout planning, a countermeasure can be taken by inserting a delay buffer.

Although in the foregoing some preferred embodiments of the present invention have been described, the present invention may be embodied in other specific forms without departing from the spirit or essential characteristics of the invention.

For instance, the combination circuit may include other than two-input AND gates.

In the foregoing the present invention has been described along with the embodiments of scan diagnosis according to the JTAG standard, in the technical field of the invention, it is to be understood that the present invention is not to be limited to the details herein given but may be modified to conform to a variety of scan diagnosis methods.

The present invention may be applied in cases where a scan test is performed.

The primary effect of the present invention may be summarized as follows.

The test of semiconductor integrated circuits will be facilitated when the present invention is applied.

1. A semiconductor integrated circuit comprising:
a combination circuit, and
a scan diagnosis circuit capable of performing a scan test of said combination circuit;
wherein
said scan diagnosis circuit comprises:
a first scan chain having a plurality of scan flip-flops connected for operating in synchronization with a clock signal;
a second scan chain placed behind said first scan chain, and having a plurality of scan flip-flops connected for operating in synchronization with the clock signal;
a first clock buffer for supplying the clock signal in the direction opposite to the flow direction of scan test data that passes through said first scan chain;
a second clock buffer for supplying the clock signal in the direction opposite to the flow direction of scan test data that passes through said second scan chain; and
a return path for sending scan test data output from a scan flip-flop placed at a closest position to said first clock buffer in said first scan chain to a scan flip-flop placed at a furthermost position from said second clock buffer in said second scan chain.

2. A semiconductor integrated circuit according to claim 1, wherein
said return path is formed of a wiring finer than a wiring forming a feeder line of said clock signal.

3. A semiconductor integrated circuit according to claim 1, wherein
the circuit has multilayered wirings with resistance per unit length differing between layers, and said return path is formed of a wiring having higher resistance than a wirings forming a feeder line of said clock signal.

4. A semiconductor integrated circuit according to claim 1, wherein
an area for inserting delay elements on the scan test data path in said return path is predefined to insert said delay elements in the area.

5. A semiconductor integrated circuit according to claim 1, further comprising
a third clock buffer for scan test, capable of delaying the output signal of said first clock buffer; and
a selector, capable of supplying the output signal of said third clock buffer instead of the output from said first clock buffer at the time of scan test to said first scan chain.

6. A semiconductor integrated circuit comprising:
a scan diagnosis circuit capable of performing a scan test of a circuit, wherein
said scan diagnosis circuit includes a clock buffer, and a plurality of scan flip-flops dispersed on the area to which the clock signal is supplied from said clock buffer; and
said scan diagnosis circuit has a scan chain connection in the order of the scan flip-flop having the largest delay of the clock signal from said clock buffer to said scan flip-flop.

7. A semiconductor integrated circuit comprising:
a combination circuit, and
a scan diagnosis circuit capable of performing a scan test of said combination circuit;
said scan diagnosis circuit comprising:
a plurality of first flip-flops having first clock signal line connected;
a plurality of second flip-flops having second clock signal line connected;
a first clock buffer connected to said first clock signal line; and
a second clock buffer connected to said second clock signal line;
wherein
said first clock buffer supplies a first clock signal to said first clock signal line;
said second clock buffer supplies a second clock signal to said second clock signal line;
said plurality of first flip-flops is formed on a first virtual line extending in a first direction, having data transferred from one end to the other end of said plurality of first flip-flops at the time of scan test;
said plurality of second flip-flops is formed on a second virtual line, which is in parallel to said first virtual line, having data from one end to the other end of said plurality of second flip-flops at the time of scan test;
data output from the other end of said plurality of first flip-flops is input to the one end of said plurality of second flip-flops;
said first clock buffer is configured such that the distance from said first clock buffer to the other end of said plurality of first flip-flops is shorter than the distance from said first clock buffer to the one end of said plurality of first flip-flops; and
said second clock buffer is configured such that the distance from said second clock buffer to the other end of said plurality of second flip-flops is shorter than the distance from said second clock buffer to the one end of said plurality of second flip-flops.

8. A semiconductor integrated circuit according to claim 7, further comprising:
a third clock buffer for supplying a common clock signal to said first clock buffer and said second clock buffer.

9. A semiconductor integrated circuit according to claim 7, wherein
a resistance of a wiring for connecting the other end of said plurality of first flip-flops with the one end of said plurality of second flip-flops is greater than a resistance of a first clock signal wiring and of a second clock signal wiring.

10. A semiconductor integrated circuit according to claim 9, wherein
a wiring connecting the other end of said plurality of first flip-flops with the one end of said plurality of second flip-flops is finer than said first clock signal wiring and said second clock signal wiring.

11. A semiconductor integrated circuit according to claim 7, wherein
said combination circuit is disposed between said plurality of first flip-flops and said plurality of second flip-flops.

12. A semiconductor integrated circuit according to claim 7, further comprising
a fourth clock buffer connected to said second clock buffer, and
a selector for selecting one of a path for supplying said second clock signal directly from said second clock buffer to said plurality of second flip-flops or a path for supplying said second clock signal through said second and fourth clock buffers to said plurality of second flip-flops.

13. A semiconductor integrated circuit according to claim 2, wherein
an area for inserting delay elements on a scan test data path in said return path is predefined to insert said delay elements in the area.

14. A semiconductor integrated circuit according to claim 3, wherein
an area for inserting delay elements on a scan test data path in said return path is predefined to insert said delay elements in the area.

15. A semiconductor integrated circuit according to claim 2, further comprising
a third clock buffer for scan test, capable of delaying the output of the clock signal of said first clock buffer; and
a selector, capable of supplying the clock signal of said third clock buffer instead of the clock signal from said first clock buffer at the time of scan test to said first scan chain.

16. A semiconductor integrated circuit according to claim 3, further comprising
a third clock buffer for scan test, capable of delaying the output of the clock signal of said first clock buffer; and
a selector, capable of supplying the clock signal of said third clock buffer instead of the clock signal from said first clock buffer at the time of scan test to said first scan chain.

17. A semiconductor integrated circuit according to claim 4, further comprising
a third clock buffer for scan test, capable of delaying the output of the clock signal of said first clock buffer; and
a selector, capable of supplying the clock signal of said third clock buffer instead of the clock signal from said first clock buffer at the time of scan test to said first scan chain.
